(19) United States
(12) Patent Application Publication
(10) Pub. No.: US 2016/0189999 A1
(43) Pub. Date: Jun. 30, 2016

(54) SEMICONDUCTOR DEVICE AND METHOD OF MANUFACTURING THE SAME

(71) Applicant: MACRONIX International Co., Ltd., Hsinchu (TW)

(72) Inventor: Chia-Wen Cheng, Hsinchu (TW)

(21) Appl. No.: 14/582,918

(22) Filed: Dec. 24, 2014

(51) Int. Cl. H01L 21/764; H01L 21/02; H01L 29/06; H01L 21/8234; H01L 21/768; H01L 23/528; H01L 23/532; H01L 27/115; H01L 21/285

(52) U.S. Cl. CPC H01L 21/764; H01L 27/11563; H01L 21/02274; H01L 29/0649; H01L 21/28518; H01L 21/76877; H01L 23/528; H01L 23/53209; H01L 21/823481

(57) ABSTRACT

Provided is a semiconductor device and a method of manufacturing the same. The semiconductor device includes a plurality of stacked structures and a dielectric layer. The stacked structures are disposed on a substrate. The dielectric layer is disposed on the substrate, and covers the stacked structures. An air gap is located between two adjacent stacked structures, and a top end of the air gap is higher than a top end of each of the stacked structures.

### BACKGROUND OF THE INVENTION

1. Field of the Invention

The invention relates to a semiconductor device and a method of manufacturing the same, and particularly relates to a semiconductor device having an air gap and a method of manufacturing the same.

2. Description of Related Art

Under the current trend of increasing the integration of semiconductor devices, a device dimension may be reduced according to design rules. However, as the dimension becomes smaller, a resistor-capacitor (RC) delay and an electrical interference among components make the speed of integrated circuits limited and influence the reliability and stability thereof. Thus, the lower performance of semiconductor devices due to RC delay is certainly an issue to be worked on.

### SUMMARY OF THE INVENTION

The invention provides a semiconductor device and a method of manufacturing the same. According to the semiconductor device and the method of manufacturing the same of the invention, an air gap is formed between adjacent gate structures, so as to effectively prevent a resistor-capacitor delay between the gate structures and reduce an electrical interference between the components, thereby improving an efficiency of the semiconductor device.

The invention provides a semiconductor device, including a plurality of stacked structures disposed on a substrate and a dielectric layer disposed on the substrate and covering the stacked structures. An air gap is located between two adjacent stacked structures, and a top end of the air gap is higher than a top end of each of the stacked structures.

According to an embodiment of the invention, in the semiconductor device, the air gap has a wide part and a narrow part, and the wide part is located below the narrow part.

According to an embodiment of the invention, in the semiconductor device, a cross-section of the air gap is in a shape of a bowling pin.

According to an embodiment of the invention, in the semiconductor device, each of the stacked structures includes a metal silicide layer, the metal silicide layer has a first part and a second part, the first part is located below the second part, and a maximum width of the first part of the metal silicide layer is less than a maximum width of the second part of the metal silicide layer.

According to an embodiment of the invention, in the semiconductor device, the maximum width of the first part of the metal silicide layer is 60% to 75% of the maximum width of the second part of the metal silicide layer.

According to an embodiment of the invention, in the semiconductor device, a cross-section of the metal silicide layer is in a shape of a mushroom.

According to an embodiment of the invention, in the semiconductor device, a maximum width of the wide part of the air gap is between two adjacent stacked structures, and is lower than the second part of the metal silicide layer.

According to an embodiment of the invention, in the semiconductor device, the air gap has a wide part, a first narrow part, and a second narrow part, the first narrow part is located below the second narrow part, and the wide part is located between the first narrow part and the second narrow part.

According to an embodiment of the invention, in the semiconductor device, a cross-section of the air gap is in a shape of a flying saucer.

According to an embodiment of the invention, in the semiconductor device, each of the stacked structures includes a metal silicide layer and a hard mask layer, the hard mask layer is disposed on the metal silicide layer, the metal silicide layer has a first part and a second part, the first part of the metal silicide layer is located below the second part of the metal silicide layer, and a maximum width of the first part of the metal silicide layer is greater than a maximum width of the second part of the metal silicide layer.

According to an embodiment of the invention, in the semiconductor device, the maximum width of the second part of the metal silicide layer is 85% to 90% of the first part of the metal silicide layer.

According to an embodiment of the invention, in the semiconductor device, a cross-section of the metal silicide layer is in an inverted T shape.

According to an embodiment of the invention, in the semiconductor device, a maximum width of the wide part of the air gap is between two adjacent stacked structures, lower than the hard mask layer, and higher than the first part of the metal silicide layer.

The invention also provides a method of manufacturing a semiconductor device, including: forming a plurality of stacked structures on the substrate; forming a first dielectric layer between two adjacent stacked structures, an upper surface of the first dielectric layer being lower than an upper surface of each of the stacked structures, and exposing a part of each of the stacked structures; forming a metal silicide layer with a part of each of the stacked structures; removing a part of the first dielectric layer to form a plurality of recesses; and forming a second dielectric layer on the substrate to cover the stacked structures, and forming an air gap between two adjacent stacked structures, wherein a top end of the air gap is higher than a top end of each of the stacked structures.

According to an embodiment of the invention, the method of manufacturing the semiconductor device further includes: forming a spacer on a sidewall of the exposed part of the stacked structure, wherein the spacer includes amorphous silicon or polysilicon; and forming a part of the metal silicide layer with the spacer.

According to an embodiment of the invention, in the method of manufacturing the semiconductor device, the metal silicide layer has a first part and a second part, the first part is located below the second part, and a maximum width of the first part is less than a maximum width of the second part.

According to an embodiment of the invention, in the method of manufacturing the semiconductor device, the metal silicide layer has a first part and a second part, the first part is located below the second part, and a maximum width of the first part is greater than a maximum width of the second part.

According to an embodiment of the invention, in the method of manufacturing the semiconductor device, the recesses covers parts of sidewalls of the metal silicide layers and parts of sidewalls of the stacked structures.

According to an embodiment of the invention, in the method of manufacturing the semiconductor device, a method of forming the second dielectric layer includes plasma enhanced chemical vapor deposition.

Based on the above, according to the semiconductor device and the method of manufacturing the semiconductor device provided by the invention, the air gap may be formed between two adjacent gate structures, and a height of the formed air gap is higher than the gate structure. Therefore, a resistor-capacitor delay between the gate structures may be effectively prevented and an electrical interference between the components may be reduced, thereby improving an efficiency of the semiconductor device.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1H are cross-sectional schematic views illustrating a method of manufacturing a semiconductor device according to an embodiment of the invention.

FIGS. 2A to 2F are cross-sectional schematic views illustrating a method of manufacturing a semiconductor device according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the following embodiments, like or similar reference symbols represent like or similar components formed of the same or similar materials or by the same or similar methods. For example, a material of a first dielectric material layer 210 of the second embodiment is the same as or similar to a material of a first dielectric material layer 110 of the first embodiment, or a method of forming the first dielectric material layer 210 of the second embodiment is the same as or similar to a method of forming the first dielectric material layer 110 of the first embodiment.

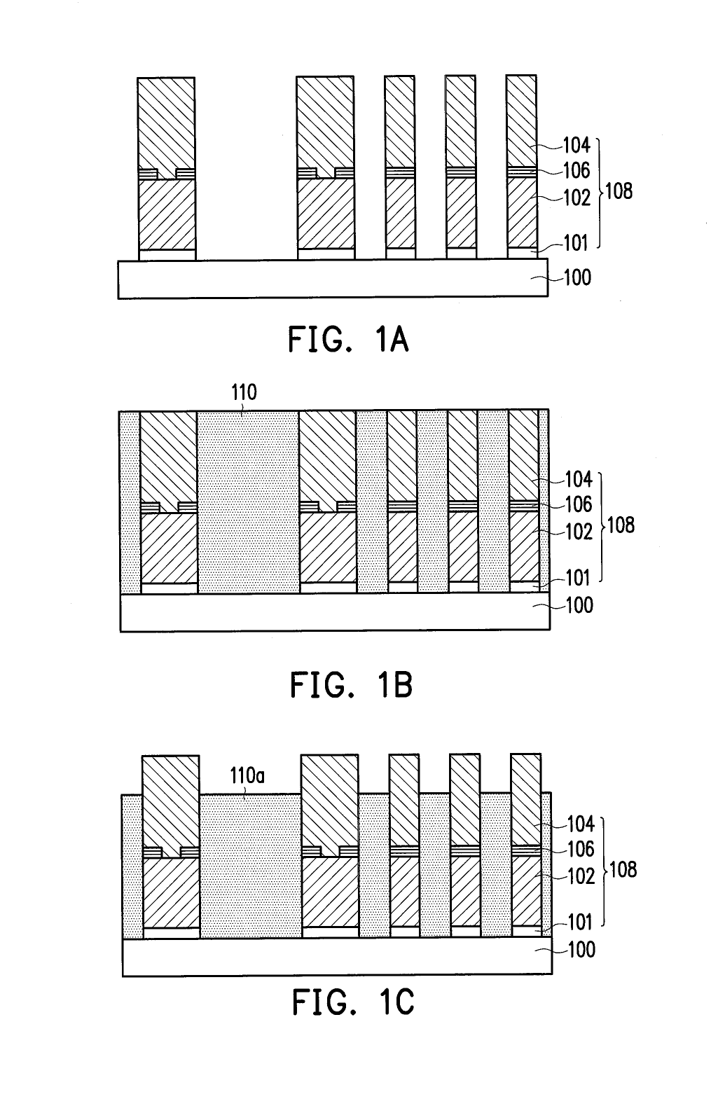

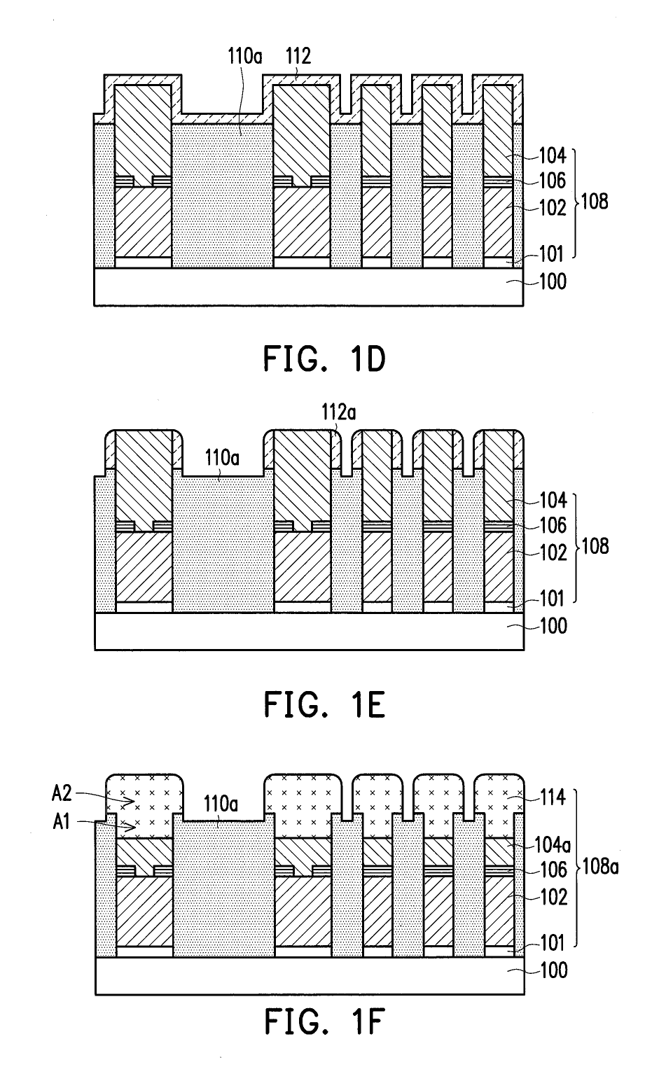

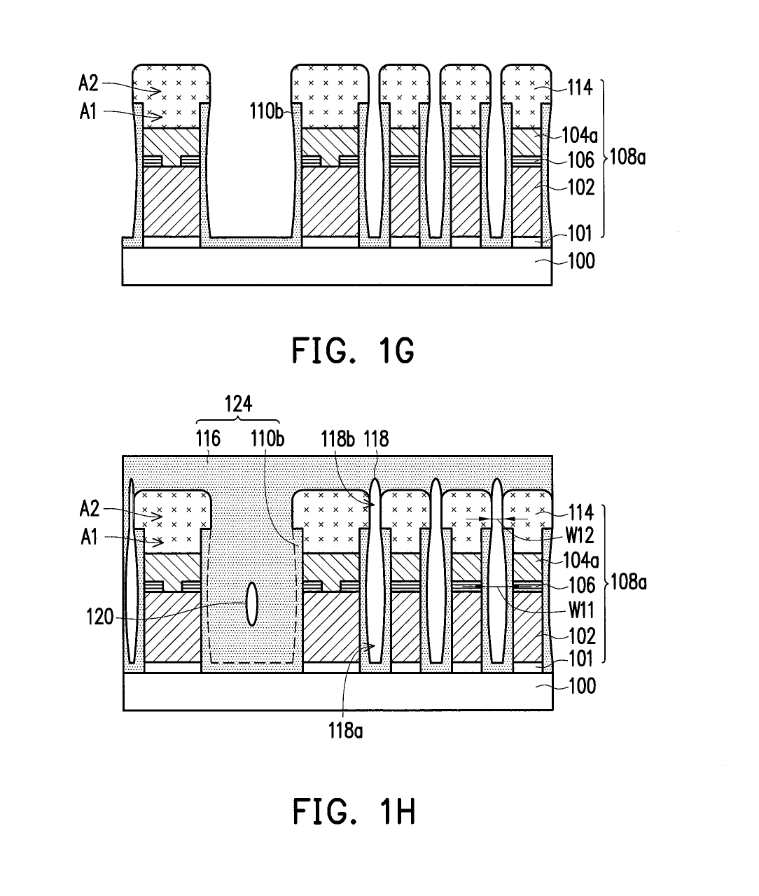

FIGS. 1A to 1H are cross-sectional schematic views illustrating a method of manufacturing a semiconductor device according to the first embodiment of the invention.

Referring to FIG. 1A, a substrate 100 is provided. The substrate 100 is, for example, a semiconductor substrate, a semiconductor compound substrate, or a semiconductor over insulator (SOI) substrate, for example. The semiconductor is atoms of WA Group, for example, such as silicon or germanium, for example. The semiconductor compound is a semiconductor compound formed of atoms of IVA Group, such as silicon carbide or germanium silicide, for example, or a semiconductor compound formed of atoms of IIIA Group and VA Group, such as gallium arsenide, for example. The substrate 100 may be doped. A dopant of the substrate 100 may be P-type or N-type. The P-type dopant may be ions of IIIA Group, such as boron ions, for example. The N-type dopant may be ions of VA Group, such as arsenic or phosphorus, for example.

Continuing to refer to FIG. 1A, a plurality of stacked structures 108 are formed on the substrate 100. In an embodiment, each of the stacked structures 108 includes a tunneling dielectric layer 101, a charge storage layer 102, and a conductive layer 104. The tunneling dielectric layer 101 is located between the corresponding charge storage layer 102 and the substrate 100. A material of the tunneling dielectric layer 101 is silicon oxide, silicon nitride, silicon oxynitride, or a combination thereof, for example. A method of forming the tunneling dielectric layer 101 is a chemical vapor deposition method or a thermal oxidation method, for example. In an embodiment, the charge storage layer 102 is a floating gate, and a material of the charge storage layer 102 includes a conductor, such as polysilicon. In another embodiment, the charge storage layer 102 is a charge trapping layer and formed of a dielectric material. The charge trapping layer may be a stacked layer, such as an oxide-nitride-oxide (ONO) layer, for example. Namely, the charge trapping layer includes layers of silicon oxide, silicon nitride, and silicon oxide therein, and a method of forming the charge trapping layer is a chemical vapor deposition method, for example. The conductive layer 104 serves as a control gate, and a material of the conductive layer 104 may be a conductor, such as doped polysilicon, polycide, a metal layer, or other applicable conductors, for example, and a method of forming the conductive layer 104 is a chemical vapor deposition method, for example. In an embodiment, the charge storage layer 102 is a floating gate, and an interlayer dielectric layer 106 is further disposed between charge storage layer 102 and the conductive layer 104. The interlayer dielectric layer 106 may be a stacked layer, such as an ONO layer, for example. A method of forming the interlayer dielectric layer 106 is a chemical vapor deposition method or a thermal oxidation method, for example.

Referring to FIG. 1B, the first dielectric material layer 110 is formed on the substrate 100, so as to fill the first dielectric material layer 110 between the plurality of stacked structures 108. A material of the first dielectric material layer 110 is oxide. Oxide is spin-on glass (SOG), high density plasma (HDP) oxide, or undoped silicate glass (USG), for example. A method of forming the first dielectric material layer 110 is, for example, performing a chemical vapor deposition process or a spin-on coating, and then performing a planarization process. The planarization process may be a chemical mechanical polishing process or an etching back process.

Referring to FIG. 1C, a part of the first dielectric material layer 110 is removed to form a first dielectric layer 110a and expose parts of the conductive layers 104. In an embodiment, an anisotropic etching process may be performed to remove the part of the first dielectric material layer 110 to form the first dielectric layer 110a and expose the parts of the conductive layers 104. The anisotropic etching process is a dry etching process, for example.

Referring to FIGS. 1D and 1E, a spacer material layer 112 is formed on the substrate 100, and covers the exposed part of the conductive layer 104. A material of the spacer material layer 112 includes a conductor, such as amorphous silicon or polysilicon, for example, and a method of forming the spacer material layer 112 is a chemical vapor deposition method, for example. A thickness of the spacer material layer 112 is from 5 nm to 10 nm, for example. Then, a part of the spacer material layer 112 is removed to form spacers 112a on sidewalls of the exposed parts of the conductive layers 104. A method of removing the part of the spacer material layer 112 is an anisotropic etching process, for example.

Referring to FIG. 1F, a metal silicidation process is performed to the spacer 112a and a part of the conductive layer 104 so as to form a metal silicide layer 114. A material of the metal silicide layer 114 may be silicide of titanium, tungsten, cobalt, nickel, copper, molybdenum, tantalum, erbium, zirconium, or platinum. In an embodiment, the material of the metal silicide layer 114 is cobalt silicide (CoSi), for example. At this time, the metal silicidation process is performed by, for example, depositing a cobalt layer, performing a first rapid thermal process (RTP), performing cobalt silicide selective etching to remove unreacted cobalt, and then performing a second rapid thermal process to cause reaction of cobalt with silicon in the spacer 112a and the part of the conductive layer 104, so as to form the metal silicide layer 114 formed of cobalt silicide. The metal silicide layer 114 has a first part A1 and a second part A2. The first part A1 is located below the second part A2. A maximum width of the first part A1 is less than a maximum width of the second part A2. In an embodiment, the maximum width of the first part A1 is 60% to 75% of the maximum width of the second part A2, making a cross-section of the metal silicide layer 114 in a shape of a mushroom.

Referring to FIG. 1G, a part of the first dielectric layer 110a is removed to form a first dielectric layer 110b. A method of removing the part of the first dielectric layer 110a is a wet etching process or a dry etching process, for example. The first dielectric layer 110b is recess-like and covers a sidewall of the first part A1 and a sidewall of a part of each of a plurality of stacked structures 108a. Each of the stacked structures 108 includes the tunneling dielectric layer 101, the charge storage layer 102, the interlayer dielectric layer 106, the conductive layer 104 and the metal silicide layer 114. A thickness of the first dielectric layer 110b is from 5 nm to 10 nm, for example.

Referring to FIG. 1H, a second dielectric layer 116 is formed on the substrate 100. The second dielectric layer 116 covers the stacked structures 108a, and forms an air gap 118 between two adjacent stacked structures 108a. A material of the second dielectric layer 116 is oxide. The material of the second dielectric layer 116 may be the same as or different from the material of the first dielectric layer 110a. A method of forming the second dielectric layer 116 includes chemical vapor deposition, such as plasma enhanced chemical vapor deposition, for example. By appropriately controlling a deposition rate of the second dielectric layer 116, an amount of the second dielectric layer 116 filled into the recess of the first dielectric layer 110b may be reduced or the second dielectric layer 116 may be prevented from being filled into the recess of the first dielectric layer 110b, so as to form the air gap 118 with a suitable size.

In an embodiment of the invention, a top end of the air gap 118 is higher than a top end of each of the stacked structures 108a. More specifically, the air gap 118 has a wide part 118a and a narrow part 118b. The wide part 118a is located below the narrow part 118b. A maximum width W11 of the wide part 118a is greater than a maximum width W12 of the narrow part 118b. The maximum width W11 of the wide part 118a is between two adjacent stacked structures 108a, and lower than the second part A2 of the metal silicide layer 114. The narrow part 118b is located between the second parts A2 of the metal silicide layers 114, and a top end of the narrow part 118b is higher than a top surface of the second part A2 of the metal silicide layer 114. In an embodiment, a cross-section of the air gap 118 may be in a shape of a bowling pin.

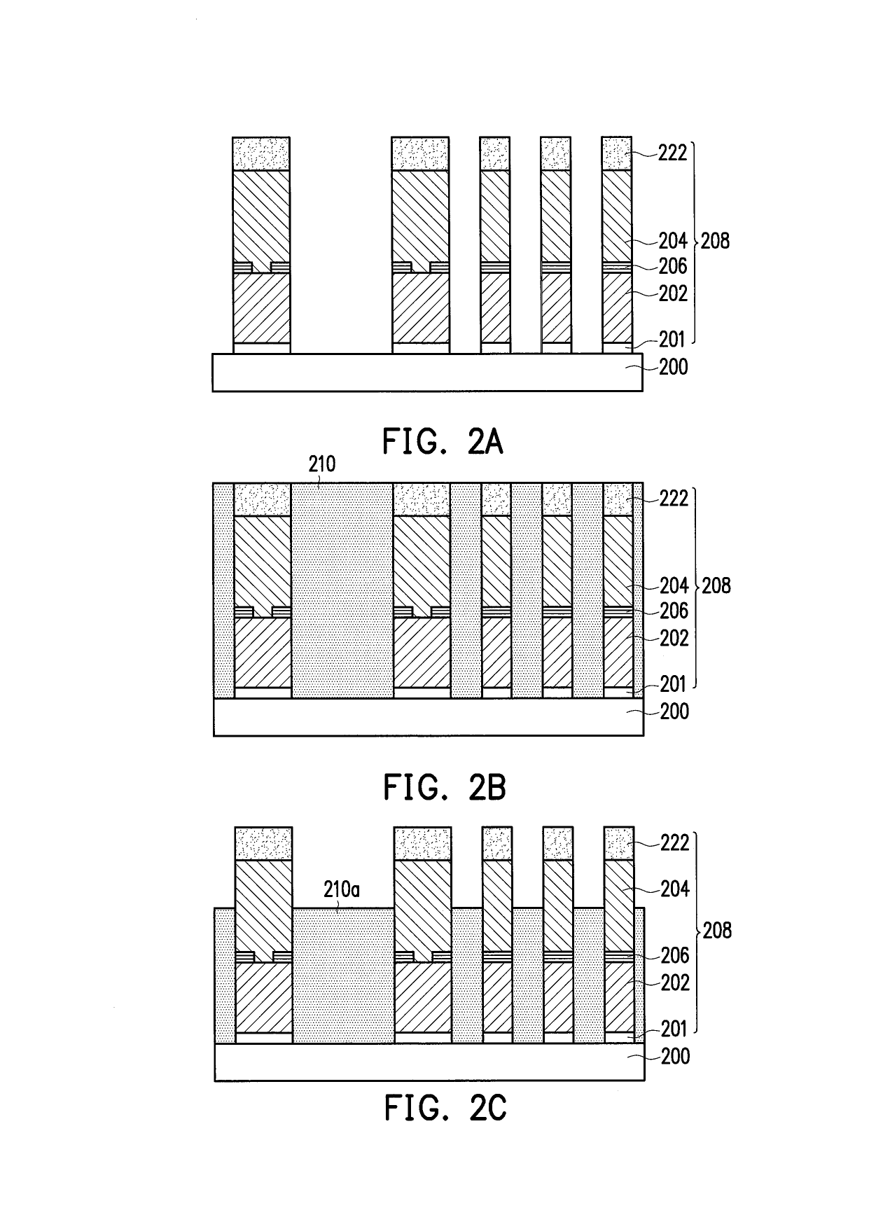

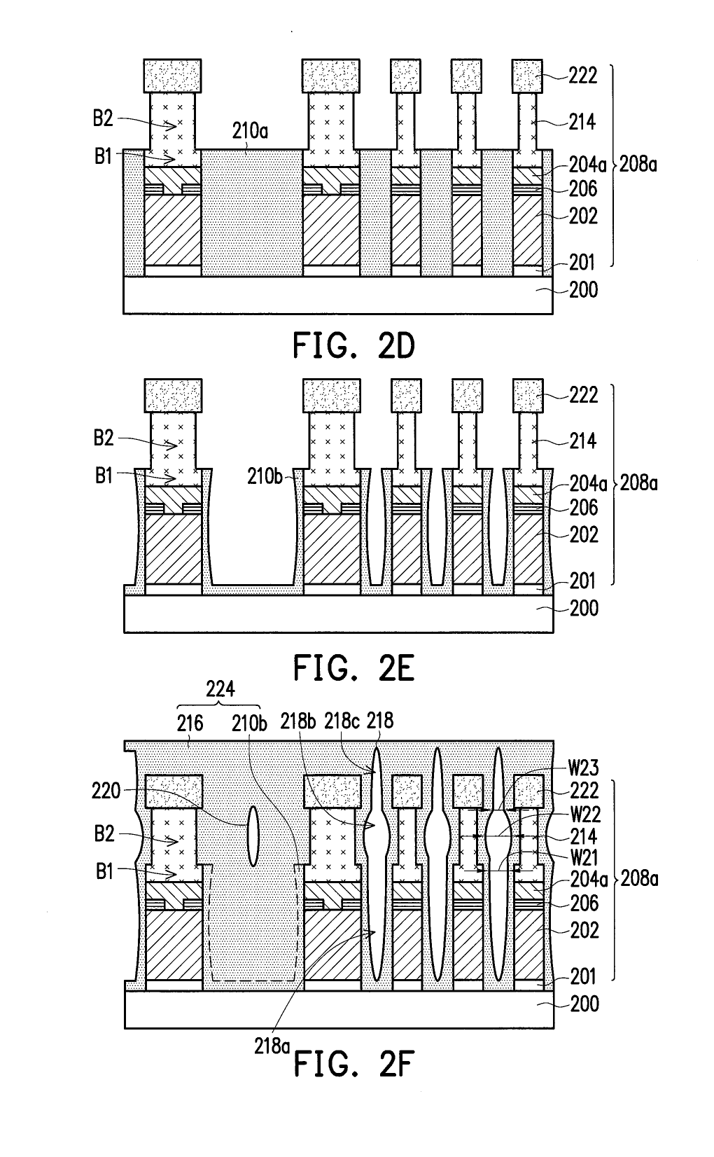

FIGS. 2A to 2F are cross-sectional schematic views illustrating a method of manufacturing a semiconductor device according to the second embodiment of the invention.

Referring to FIG. 2A, by using the method and material described in the first embodiment, a plurality of stacked structures 208 are formed on a substrate 200. In an embodiment, each of the stacked structures 208 includes a tunneling dielectric layer 201, a charge storage layer 202, a conductive layer 204, and a hard mask layer 222. In another embodiment, each of the stacked structures 208 further includes an interlayer dielectric layer 206 located between the charge storage layer 202 and the conductive layer 204. A material of the hard mask layer 222 is silicon oxide, silicon nitride, silicon oxynitride (SiON), silicon carbide (SiC), silicon carbonitride (SiCN) or a combination thereof, for example, and a method of forming the hard mask layer 222 is a chemical vapor deposition method, for example. A thickness of the hard mask layer 222 is from 30 nm to 40 nm, for example.

Referring to FIGS. 2B and 2C, by using the method and material described in the first embodiment, a first dielectric material layer 210 is formed on the substrate 200, and the first dielectric material layer 210 is filled into the plurality of stacked structures 208. Then, an anisotropic etching process is performed to the first dielectric material layer 210, so as to remove a part of the first dielectric material layer 210 to form a first dielectric layer 210a and expose the hard mask layer 222 and a part of the conductive layer 204.

Referring to FIG. 2D, by using the method and material described in the first embodiment, a metal silicidation process is performed to a part of the conductive layer 204 so as to form a metal silicide layer 214. The metal silicide layer 214 has a first part B1 and a second part B2. The first part B1 is located below the second part B2. Since in the metal silicidation process, the exposed part of the conductive layer 204 may suffer from a loss of size, a maximum width of the first part B1 is greater than a maximum width of the second part B2. The maximum width of the second part B2 is, for example, 85% to 90% of the maximum width of the first part B1. In an embodiment, a cross-section of the metal silicide layer 214 is formed to be in an inverted T shape.

Referring to FIG. 2E, by using the method and material described in the first embodiment, a part of the first dielectric layer 210a is removed to form a first dielectric layer 210b. The first dielectric layer 210b is recess-like and covers a part of a sidewall of the first part B1 and a sidewall of a part of each of a plurality of stacked structures 208a. Each of the stacked structures 208a includes the tunneling dielectric layer 201, the charge storage layer 202, the interlayer dielectric layer 106, the conductive layer 104 and the metal silicide layer 214. A thickness of the first dielectric layer 210b is from 5 nm to 10 nm.

Referring to FIG. 2F, by using the method and material described in the first embodiment, a second dielectric layer 216 is formed on the substrate 200 to cover the stacked structures 208a and form an air gap 218 between two adjacent stacked structures 208a. A method of forming the second dielectric layer 216 includes chemical vapor deposition, such as plasma enhanced chemical vapor deposition, for example. By appropriately controlling a deposition rate of the second dielectric layer 216, an amount of the second dielectric layer 116 filled into the recess of the first dielectric layer 210b may be reduced or the second dielectric layer 216 may be prevented from being filled into the recess of the first dielectric layer 110b, so as to form the air gap 218 with a suitable size.

A top end of the air gap 218 is higher than a top end of each of the stacked structures 208a. The air gap 218 has a wide part 218b, a first narrow part 218a, and a second narrow part 218c. The first narrow part 218a is located below the second narrow part 218c, and the wide part 218b is located between the first narrow part 218a and the second narrow part 218c. A maximum width W22 of the wide part 218b is greater than maximum widths W21 and W23 of the first narrow part 218a and the second narrow part 218c. The maximum width W22 of the wide part 218b is between two adjacent stacked structures 208a, lower than the hard mask layer 222, and higher than the first part B1 of the metal silicide layer 214. In an embodiment, a cross-section of the air gap 218 may be in a shape of a flying saucer.

Referring to FIG. 1H again, a semiconductor device according to an embodiment of the invention includes the substrate 100, the plurality of stacked structures 108a, and the dielectric layer 124. The air gap 118 is located between two adjacent stacked structures 108a. Each of the stacked structures 108a includes the metal silicide layer 114. The metal silicide layer 114 has the first part A1 and the second part A2. The first part A1 is located below the second part A2, and the maximum width of the first part A1 is less than the maximum width of the second part A2. In an embodiment, the maximum width of the first part A1 is 60% to 75% of the maximum width of the second part A2, making the cross-section of the metal silicide layer 114 in the shape of a mushroom. The top end of the air gap 118 is higher than the top end of each of the stacked structures 108a. The air gap 118 has the wide part 118a and the narrow part 118b, the wide part 118a is located below the narrow part 118b, and the maximum width W11 of the wide part 118a is greater than the maximum width W12 of the narrow part 118b. In an embodiment, the maximum width W11 of the wide part 118a is between two adjacent stacked structures 108a, and lower than the second part A2 of the metal silicide layer 114. The cross-section of the air gap 118 may be in the shape of a bowling pin.

Referring to FIG. 2F again, a semiconductor device according to another embodiment of the invention includes the substrate 200, the plurality of stacked structures 208a, and the dielectric layer 224. The air gap 218 is located between two adjacent stacked structures 208a. Each of the stacked structures 208a includes the metal silicide layer 214 and the hard mask layer 222, and the hard mask layer 222 is disposed on the metal silicide layer 214. The metal silicide layer 214 has the first part B1 and the second part B2. The first part B1 is located below the second part B2, and the maximum width of the first part B1 is greater than the maximum width of the second part B2. In an embodiment, the maximum width of the second part B2 is 85% to 90% of the maximum width of the first part B1, so that the cross-section of the metal silicide layer 214 is formed to be in an inverted T shape. The top end of the air gap 218 is higher than the top end of each of the stacked structures 208a. The air gap 218 has the wide part 218b, the first narrow part 218a, and the second narrow part 218c. The first narrow part 218a is located below the second narrow part 218c, and the wide part 218b is located between the first narrow part 218a and the second narrow part 218c. The maximum width W22 of the wide part 218b is greater than the maximum widths W21 and W23 of the first narrow part 218a and the second narrow part 218c. The maximum width W22 of the wide part 218b is between two adjacent stacked structures 208a, lower than the hard mask layer 222, and higher than the first part B1 of the metal silicide layer 214. The cross-section of the air gap 218 may be in the shape of a flying saucer.

In the above embodiments, the semiconductor device is described as a non-volatile memory device. The non-volatile memory device may be a flash memory or a charge trapping memory. However, the semiconductor device of the invention is not limited to the above embodiments. The semiconductor device may also be a metal oxide semiconductor transistor. The metal oxide semiconductor transistor may be a planar type transistor or a fin type transistor.

In view of the foregoing, according to the semiconductor device and the method of manufacturing the same provided by the invention, the air gap may be formed between two adjacent gate structures. Since the top end of the formed air gap is higher than the height of the top end of the gate structure, and takes up a certain capacity, a resistor-capacitor delay between the gate structures may be effectively prevented and an electrical interference between the components may be reduced, thereby improving an efficiency of the semiconductor device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor device, comprising:
a plurality of stacked structures, disposed on a substrate; and
a dielectric layer, disposed on the substrate and covering the stacked structures,
wherein an air gap is located between two adjacent stacked structures, and a top end of the air gap is higher than a top end of each of the stacked structures,
wherein the air gap has a wide part, a first narrow part, and a second narrow part, the first narrow part is located below the second narrow part, and the wide part is located between the first narrow part and the second narrow part,
wherein each of the stacked structures comprises a metal silicide layer and a hard mask layer, the hard mask layer is disposed on the metal silicide layer, the metal silicide layer has a first part and a second part, the first part of the metal silicide layer is located below the second part of the metal silicide layer, and a maximum width of the first part of the metal silicide layer is greater than a maximum width of the second part of the metal silicide layer.

2-8. (canceled)

9. The semiconductor device as claimed in claim 1, wherein a cross-section of the air gap is in a shape of a flying saucer.

10. (canceled)

11. The semiconductor device as claimed in claim 1, wherein the maximum width of the second part of the metal silicide layer is 85% to 90% of the first part of the metal silicide layer.

12. The semiconductor device as claimed in claim 1, wherein a cross-section of the metal silicide layer is in an inverted T shape.

13. The semiconductor device as claimed in claim 1, wherein a maximum width of the wide part of the air gap is between two adjacent stacked structures, lower than the hard mask layer, and higher than the first part of the metal silicide layer.

14-19. (canceled)
